(19) United States
(12) Patent Application Publication
(10) Pub. No.: US 2024/0266366 A1
(43) Pub. Date: Aug. 8, 2024

(54) FLEXIBLE DISPLAY PANEL AND FLEXIBLE DISPLAY DEVICE

(71) Applicants: Wuhan Tianma Microelectronics Co., Ltd., Wuhan (CN); Wuhan Tianma Microelectronics Co., Ltd. Shanghai Branch, Shanghai (CN)

(72) Inventors: Qibing WEI, Wuhan (CN); Peng ZHANG, Wuhan (CN); Xingyao ZHOU, Wuhan (CN)

(73) Assignees: Wuhan Tianma Microelectronics Co., Ltd., Wuhan (CN); Wuhan Tianma Microelectronics Co., Ltd. Shanghai Branch, Shanghai (CN)

(21) Appl. No.: 18/639,052

(22) Filed: Apr. 18, 2024

(30) Foreign Application Priority Data
Nov. 28, 2023 (CN) 202311623064.2

(51) Int. Cl. H01L 27/12

(52) U.S. Cl. CPC H01L 27/1248

(57) ABSTRACT

A flexible display panel and a flexible display device are provided. The flexible display panel has a display region and a non-display region and includes an inorganic layer and a signal lead-out line. In an embodiment, the non-display region includes a bending region and a binding region. In an embodiment, the bending region is located between the display region and the binding region. In an embodiment, the inorganic layer is located in the display region and the non-display region. In an embodiment, the blank region includes at least one first blank region, and a portion of the inorganic layer located in one of the at least one first blank region includes at least one first stress groove.

### CROSS-REFERENCE TO RELATED APPLICATIONS

The present application claims priority to Chinese Patent Application No. 202311623064.2, filed on Nov. 28, 2023, the content of which is incorporated herein by reference in its entirety.

### TECHNICAL FIELD

The present disclosure relates to the field of display technologies, and, particularly, relates to a flexible display panel and a flexible display device.

### BACKGROUND

In the manufacturing process of the flexible display panel, after the binding region is bent to the back side of the display region, the binding region is pressed down by an indenter to press the binding region and the display region together. However, during the pressing process, peeling of the layer in the binding region is likely to occur under stress.

### SUMMARY

In view of this, embodiments of the present disclosure provide a flexible display panel and a flexible display device to solve the layer peeling problem during the pressing process.

In one aspect, embodiments of the present disclosure provide a flexible display panel. The flexible display panel has a display region and a non-display region and includes an inorganic layer and a signal lead-out line. The non-display region includes a bending region and a binding region. The bending region is located between the display region and the binding region. The inorganic layer is located in the display region and the non-display region. The blank region includes at least one first blank region, and a portion of the inorganic layer located in one of the at least one first blank region includes at least one first stress groove.

In another aspect, embodiments of the present disclosure provide a flexible display device including a flexible display panel. The flexible display panel has a display region and a non-display region and includes an inorganic layer and a signal lead-out line. The non-display region includes a bending region and a binding region. The bending region is located between the display region and the binding region. The inorganic layer is located in the display region and the non-display region. The blank region includes at least one first blank region, and a portion of the inorganic layer located in one of the at least one first blank region includes at least one first stress groove.

### BRIEF DESCRIPTION OF DRAWINGS

In order to more clearly explain the embodiments of the present disclosure or the technical solution in the related art, the drawings used in the description of the embodiments will be briefly described below. The drawings in the following description are some embodiments of the present disclosure. Those skilled in the art can obtain other drawings based on these drawings.

FIG. 1 is a schematic diagram of a flexible display panel provided by some embodiments of the present disclosure;

FIG. 2 is an unfolded schematic diagram of a flexible display panel provided by some embodiments of the present disclosure;

FIG. 3 is a schematic diagram of a binding region provided by some embodiments of the present disclosure;

FIG. 4 is a partial schematic diagram of a binding region provided by some embodiments of the present disclosure;

FIG. 5 is another partial schematic diagram of s binding region provided by some embodiments of the present disclosure;

FIG. 6 is a schematic diagram of a first blank region provided by some embodiments of the present disclosure;

FIG. 7 is another schematic diagram of a first blank region provided by some embodiments of the present disclosure;

FIG. 8 is another schematic diagram of a first blank region provided by some embodiments of the present disclosure;

FIG. 9 is another schematic diagram of a first blank region provided by some embodiments of the present disclosure;

FIG. 10 is another schematic diagram of a first blank region provided by some embodiments of the present disclosure;

FIG. 11 is another partial schematic diagram of a binding region provided by some embodiments of the present disclosure;

FIG. 12 is another schematic diagram of a first blank region provided by some embodiments of the present disclosure;

FIG. 13 is another schematic diagram of a first blank region provided by some embodiments of the present disclosure;

FIG. 14 is another schematic diagram of a first blank region provided by some embodiments of the present disclosure;

FIG. 15 is another schematic diagram of a first blank region provided by some embodiments of the present disclosure;

FIG. 16 is another schematic diagram of a first blank region provided by some embodiments of the present disclosure;

FIG. 17 is another schematic diagram of a first blank region provided by some embodiments of the present disclosure;

FIG. 18 is another schematic diagram of a first blank region provided by some embodiments of the present disclosure;

FIG. 19 is another schematic diagram of a first blank region provided by some embodiments of the present disclosure;

FIG. 20 is another schematic diagram of a first blank region provided by some embodiments of the present disclosure;

FIG. 21 is a cross-sectional view of a flexible display panel provided by some embodiments of the present disclosure;

FIG. 22 is another cross-sectional view of a flexible display panel provided by some embodiments of the present disclosure;

FIG. 23 is another schematic diagram of a first blank region provided by some embodiments of the present disclosure;

FIG. 24 is another schematic diagram of a first blank region provided by some embodiments of the present disclosure; and

FIG. 25 is a schematic diagram of a flexible display device provided by some embodiments of the present disclosure.

### DESCRIPTION OF EMBODIMENTS

In order to better understand technical solutions of the present disclosure, the embodiments of the present disclosure are described in detail with reference to the drawings.

It should be clear that the described embodiments are merely part of the embodiments of the present disclosure rather than all of the embodiments. Based on the embodiments of present disclosure, all other embodiments obtained by those skilled in the art shall fall within the scope of the present disclosure.

The terms used in the embodiments of the present disclosure are merely for the purpose of describing specific embodiment, rather than limiting the present disclosure. The terms “a”, “an”, “the” and “the” in a singular form in some embodiments of the present disclosure and the attached claims are also intended to include plural forms thereof, unless noted otherwise.

It should be understood that the term “and/or” used in the context of the present disclosure is to describe a correlation relation of related objects, indicating that there can be three relations, e.g., A and/or B can indicate A alone, both A and B, and B alone. In addition, the symbol “/” in the context generally indicates that the relation between the objects in front and at the back of “/” is an “or” relationship.

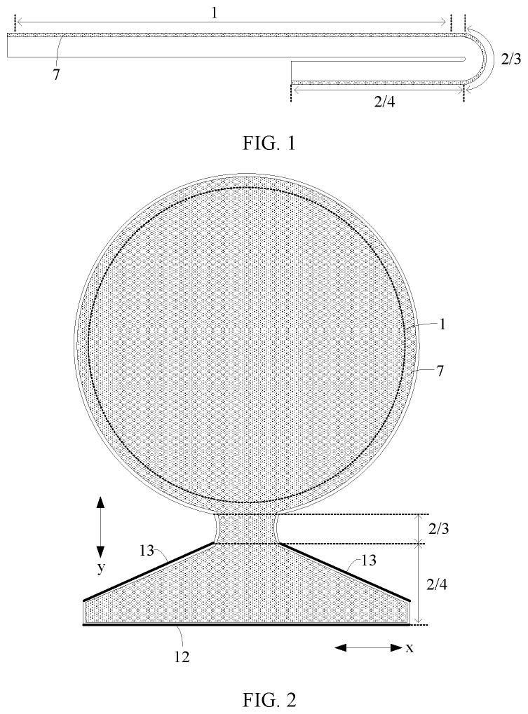

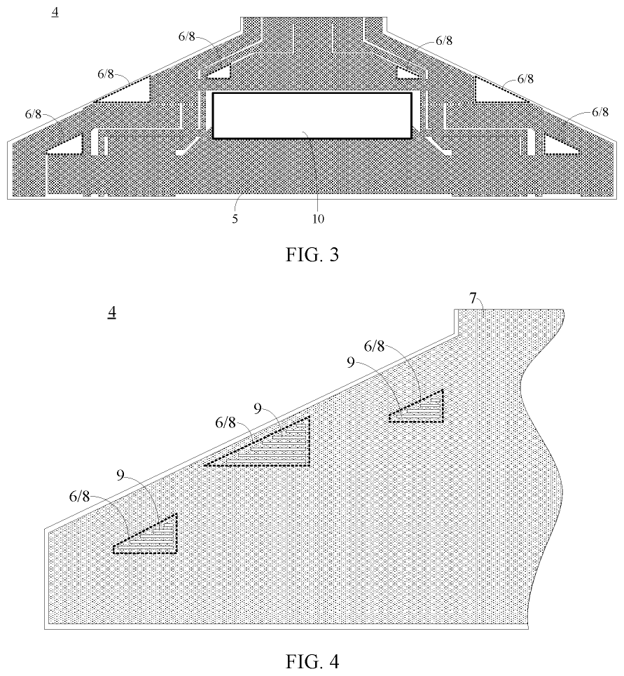

Some embodiments of the present disclosure provide a flexible display panel. FIG. 1 is a schematic diagram of a flexible display panel provided by some embodiments of the present disclosure. FIG. 2 is an unfolded schematic diagram of a flexible display panel provided by some embodiments of the present disclosure. FIG. 3 is a schematic diagram of a binding region 4 provided by some embodiments of the present disclosure. FIG. 4 is a partial schematic diagram of the binding region 4 provided by some embodiments of the present disclosure. As shown in FIGS. 1-4, the flexible display panel has a display region 1 and a non-display region 2. The non-display region 2 includes a bending region 3 and a binding region 4. The bending region 3 is located between the display region 1 and the binding region 4. Referring to FIG. 1, in the final structure of the flexible display panel, the bending region 3 is bent toward a backlight side of the display region 1 to place the binding region 4 on the backlight side of the display region 1. The binding region 4 and the display region 1 overlap in a direction perpendicular to a plane of the display region 1.

Referring to FIG. 3, the binding region 4 includes a wiring region 5 and a blank region 6. Signal lead-out lines (not shown in the figures) are provided in the wiring region 5. It can be understood that various signal lines, such as data lines and power supply lines, are provided in the display region 1, and various pins for binding a driver chip and a printed circuit board are provided in the binding region 4. The signal lead-out lines include metal lines connected between signal lines and pins and metal lines connected between different pins. In other words, the wiring region 5 can be understood as a region where the metal lines are distributed in the binding region 4, while no metal line is distributed in the blank region 6. To simplify the illustration, FIG. 3 only uses a fill pattern to illustrate approximate distribution positions of the signal lead-out lines, while not showing the signal lead-out lines.

The flexible display panel includes an inorganic layer 7 located in the display region 1 and the non-display region 2. The blank region 6 includes a first blank region 8, and a portion of the inorganic layer 7 located in the first blank region 8 includes a first stress groove 9.

It is found that, in a flexible display panel, an inorganic layer is usually used as an insulating layer between metal layers, a large number of inorganic layers are provided in the flexible display panel and cover the display panel with a large area. However, due to high brittleness of inorganic materials, when the binding region 4 of the flexible display panel is bent to the back side of the display region 1 and then pressed down by the indenter, the inorganic layer 7 in the binding region 4 easily cracks under the mechanical pressure and cause layer peeling problems. This is especially the case for chip on panel (COP) type flexible display panels, see FIG. 2. Before bending the binding region 4 of this type of flexible display panel, the driver chip 10 is bound in the binding region 4, which causes a large step difference between the position of the driver chip 10 and other positions. Then when subsequently using the indenter to apply pressure on the binding region 4, the step difference between the layers causes uneven stress at different positions, which aggravates the layer peeling problem.

In this regard, the embodiments of the present disclosure provides the first stress groove 9 in the inorganic layer 7 in at least part of the blank region 6 of the binding region 4, that is, a groove is design in the inorganic layer 7 in at least part of the blank region 6. Then, the first stress groove 9 can be used to release the stress generated during the lamination process, thereby improving the peeling problem of the layer caused by stress concentration, and improving the reliability of the binding region 4 during bending and lamination, especially improving the lamination reliability of COP flexible display panels. Since no signal lead-out line is provided in the blank region 6, the first stress groove 9 is provided without causing metal short circuit problems and without affecting the display reliability of the flexible display panel.

Put another way, after the embodiments of the present disclosure solve the layer peeling problem by using the first stress groove 9, there is no need to adjust the pressure of the indenter to avoid layer peeling, which can ensure that the flexible display panel has a better lamination performance and a higher productivity.

Referring to FIG. 3, the binding region 4 generally includes multiple blank regions 6, and the positions and areas of different blank regions 6 may be different. It is found that, in a COP type flexible display panel, in order to avoid damaging the driver chip 10, the main force-bearing point when the indenter presses down is generally at a position far away from the driver chip 10. For example, the main force-bearing point will be closer to the outer edge of the flexible display panel, which will cause the inorganic layer 7 near the outer edge of the flexible display panel to receive greater stress, and then lead to a higher risk of layer peeling. In this regard, the embodiments of the present disclosure can at least select the blank region 6 adjacent to the outer edge of the flexible display panel as the first blank region 8 to improve the layer peeling problem at the outer edge of the flexible display panel. In some embodiments of the present disclosure, at least a blank region 6 with a larger area can be selected as the first blank region 8 to reduce the process difficulty of setting the first stress groove 9 in the inorganic layer 7. A groove width of the first stress groove 9 and a groove spacing between the first stress grooves 9 can be flexibly designed. Normally, an area of the blank region 6 at a side of the outer edge of the flexible display panel is larger. Therefore, in some embodiments of the present disclosure, at least one first blank region 8 is adjacent to the outer edge of the flexible display panel, so that the layer peeling problem is improved while the groove width of the first stress groove 9 and the groove spacing between the first stress grooves 9 are flexibly designed.

The position and size of the blank regions 6 shown in the drawings of the embodiments of the present disclosure are only schematically illustrated and do not represent specific limitations on the above features. The number, the position, and the size of the blank region 6 can be designed differently according to the actual layer structure.

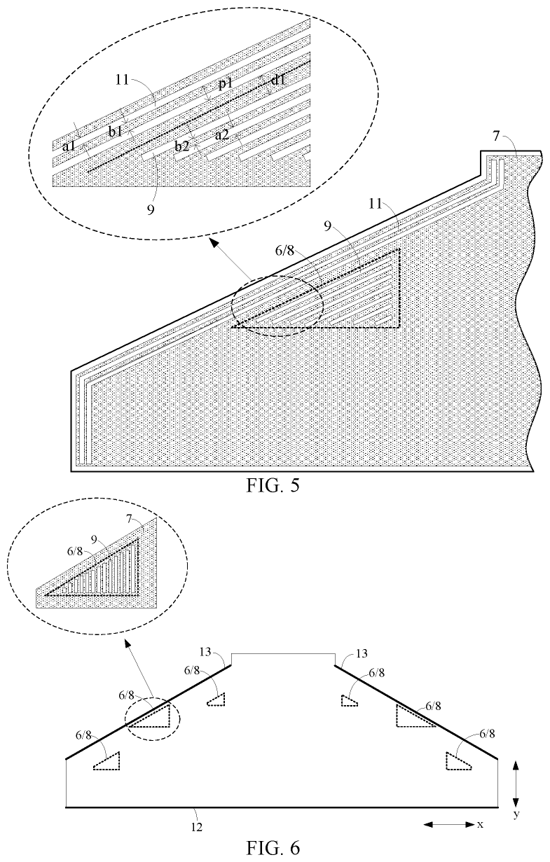

FIG. 5 is another partial structural diagram of the binding region 4 provided by some embodiments of the present disclosure. In some embodiments, as shown in FIG. 5, the inorganic layer 7 includes an anti-crack groove 11 adjacent to the outer edge of the flexible display panel. The anti-crack groove 11 extends along the outer edge of the flexible display panel at least in the binding region 4. The blank region 6 in the embodiments of the present disclosure is located away from the outer edge of the anti-crack groove 11, so that the anti-crack groove 11 is used to protect the blank region 6 to prevent cutting cracks from extending into the inside of the blank region 6.

It can be understood that two types of grooves, the anti-crack groove 11 and the first stress groove 9, can be provided in the inorganic layer 7 at the same time, but the positions and extending directions of these two types of grooves are quite different. The anti-crack groove 11 is a groove that extends continuously along the outer edge of the flexible display panel, while the first stress groove 9 is a groove that only extends within the first blank region 8. Since the blank region 6 has a relatively smaller area and multiple blank regions 6 are spaced apart from each other, so an extension length of a single first stress groove 9 will be significantly smaller than an extension length of a single anti-crack groove 11.

Referring to FIG. 5 again, at least one first blank region 8 is adjacent to the anti-crack groove 11. In the first blank region 8 adjacent to the anti-crack groove 11, a distance d1 between the first stress groove 9 and the anti-crack groove 11 is greater than or equal to p1, where p1 is a sum of a groove width of the anti-crack groove 11 and a groove spacing between this anti-crack groove 11 and its adjacent anti-crack groove 11, that is, p1 can also be understood as a pitch of the anti-crack groove 11.

For the first blank region 8 adjacent to the anti-crack groove 11, this first blank region 8 is adjacent to the outer edge of the flexible display panel, so the problem of external water and oxygen penetration is taken into consideration. In some embodiments of the present disclosure, a distance between the first stress groove 9 in this first blank region 8 and the anti-crack groove 11 is set to be relatively large, so that an inorganic layer with a sufficient width, which is provided between the anti-crack groove 11 and the first stress groove 9, can isolate water and oxygen from penetrating, which improves the water and oxygen isolation capability of the flexible display panel. Between the anti-crack groove 11 and the first stress groove 9, the mutual contact between the multiple inorganic layers 7 can increase the layer adhesion between the inorganic layers 7, which can reduce the risk of peeling of the multiple inorganic layers 7 caused by stress concentration, that is, a disguised form to suppress the peeling problem of the layer at the cutting line (the outer edge of the flexible display panel).

In some embodiments, with reference to FIGS. 6 to 9, the first stress grooves 9 located in a same first blank region 8 extend in a same direction. In this case, the first stress groove 9 in the first blank region 8 can prevent the layer peeling from extending along a direction intersecting the extending direction of the first stress groove 9 in a more targeted and greater degree. For example, referring to FIG. 6, when the first stress groove 9 in the first blank region 8 extends along the second direction y, the extension of the layer peeling in the first direction x can be blocked.

FIG. 6 is a schematic diagram of a first blank region 8 provided by some embodiments of the present disclosure. In some embodiments, in combination with FIG. 2 and FIG. 6, the binding region 4 includes a first outer edge 12, the first outer edge 12 is an edge of the binding region 4 that is furthest away from the bending region 3, and the first outer edge 12 extends along the first direction x. In at least one first blank region 8, the extending direction of the first stress groove 9 is perpendicular to the first direction x. In the embodiments of the present disclosure, the direction perpendicular to the first direction x is defined as a second direction y.

The first stress groove 9 in this first blank region 8 not only releases stress to reduce the effect of the layer peeling, but also blocks the layer peeling from extending in the first direction x in a targeted manner. For example, when the layer peeling occurs at a side of the first blank region 8 close to the second outer edge 13, multiple first stress grooves 9 in the first blank region 8, each extending in the second direction y, can prevent layer peeling from extending along the first direction for multiple times and then prevent layer peeling from extending into the binding region 4, thereby reducing the risk of adversely affecting the signal lead-out lines and the driver chip 10.

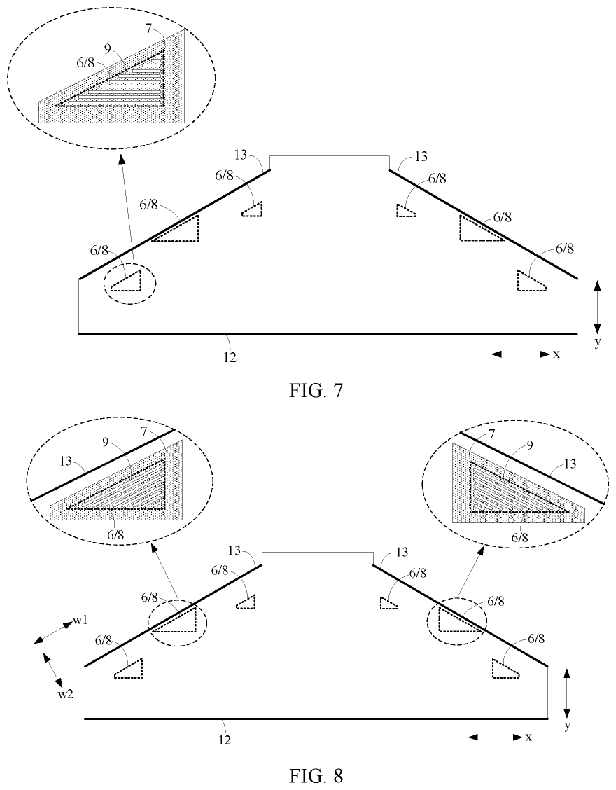

FIG. 7 is another schematic diagram of a first blank region 8 provided by some embodiments of the present disclosure. In some embodiments, in conjunction with FIG. 2 and FIG. 7, the binding region 4 includes a first outer edge 12. The first outer edge 12 is an edge of the binding region 4 that is furthest away from the bending region 3, and the first outer edge 12 extends along the first direction x. In at least one first blank region 8, the extending direction of the first stress groove 9 is parallel to the first direction x.

Similarly, the first stress groove 9 in this first blank region 8 not only releases the stress to reduce the effect of the layer peeling, but also prevents the layer peeling from extending in the second direction y in a targeted manner. For example, when the layer peeling occurs at a side of the first blank region 8 close to the first outer edge 12, multiple first stress grooves 9 in the first blank region 8 each extending in the first direction x can prevent the layer peeling from extending in the second direction y for multiple times, which prevents the layer peeling from continuously extending towards the bending region 3.

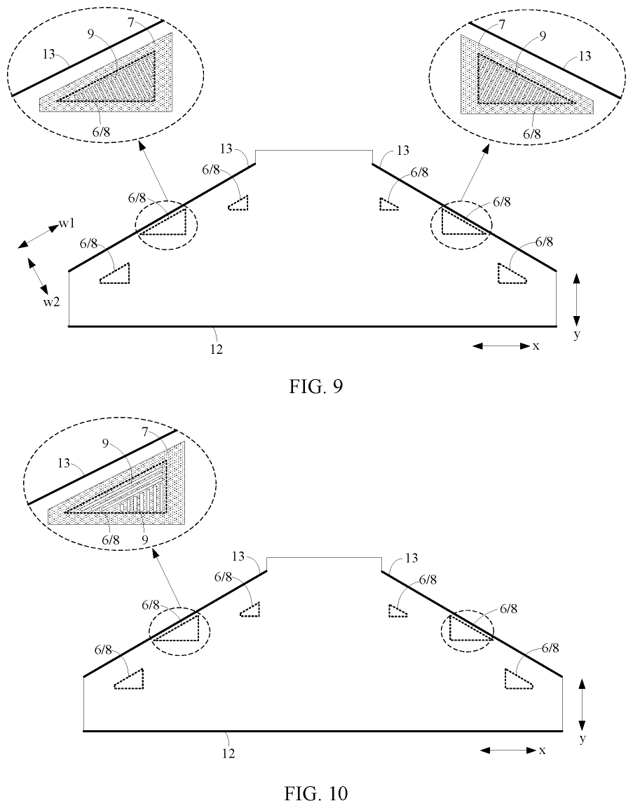

FIG. 8 is another schematic diagram of a first blank region 8 provided by some embodiments of the present disclosure. FIG. 9 is another schematic diagram of a first blank region 8 provided by some embodiments of the present disclosure. In some embodiments, in conjunction with FIG. 2, FIG. 8, and FIG. 9, the binding region 4 includes a first outer edge 12. The first outer edge 12 is an edge of the binding region 4 that is farthest from the bending region 3. The first outer edge 12 extends along the first direction x.

The binding region 4 can include a second outer edge 13, and an angle between an extending direction of the second outer edge 13 and the first direction x is smaller than 90° and not equal to 0°. At least one first blank region 8 is adjacent to the second outer edge 13. For the first blank region 8 adjacent to the second outer edge 13, the extending direction of the first stress groove 9 in this first blank region 8 is parallel to the extending direction of the second outer edge 13, and/or, the extending direction of the first stress groove 9 in this first blank region 8 is perpendicular to the extending direction of the second outer edge 13.

In some embodiments, the binding region may include two third outer edges 13, and the extending direction of the first stress groove 9 in the first blank region 8 being parallel (or perpendicular) to the extending direction of the second outer edge 13 indicates that the extending direction of the first stress groove 9 in the first blank region 8 is parallel (or perpendicular) to the extending direction of one second outer edge 13 adjacent to this first stress groove 9.

Referring to FIG. 8, when the extending direction of the first stress groove 9 in the first blank region 8 is parallel to the extending direction of the second outer edge 13, the direction of the first stress groove 9 remains consistent with the direction of the second outer edge 13, and the first stress groove 9 can prevent the layer peeling at the position of the cutting line from continuously extending into the binding region 4. For example, taking the first blank region 8 at a side of the second outer edge 13 extending along a third direction w1 as an example, when layer peeling occurs at the side of this first blank region 8 close to the second outer edge 13, multiple first stress grooves 9 in a blank region 8 each extending in the third direction w1 can prevent layer peeling from extending in the fourth direction w2 for multiple times, to prevent the layer peeling from continuously extending towards the inside of the binding region 4.

Referring to FIG. 9, when the first stress groove 9 in the first blank region 8 is perpendicular to the extending direction of the second outer edge 13, the first stress groove 9 can prevent layer peeling from extending in the extending direction of the second outer edge 13 in a targeted manner. For example, taking the first blank region 8 at the side of the second outer edge 13 extending along the third direction w1 as an example, when layer peeling occurs at a side of this first blank region 8 in the third direction w1, multiple first stress grooves 9 in the first blank region 8 each extending in the fourth direction w2 can prevent layer peeling from extending in the third direction w1 for multiple times to prevent the layer peeling from continuously extending towards the inside of the binding region 4.

In some embodiments of the present disclosure, the extending directions of the first stress grooves 9 in a same first blank region 8 may also be different. FIG. 10 is another schematic diagram of a first blank region 8 provided by some embodiments of the present disclosure. For example, as shown in FIG. 10, for the first blank region 8 adjacent to the second outer edge 13, at least one first stress groove 9 in the first blank region 8 may extend in a direction parallel to the extending direction of the second outer edge 13, and the at least one first stress groove 9 is adjacent to the second outer edge 13, so as to prevent cracks and peeling caused by cutting or pressing at the second outer edge 13, and the remaining first stress grooves 9 can extend along the first direction x and/or the second direction y.

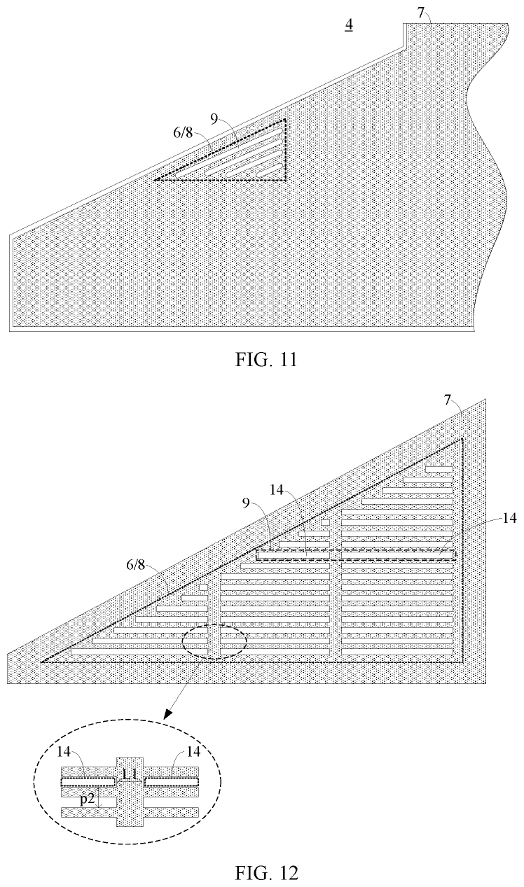

In some embodiments, referring to FIG. 6 to FIG. 9 again, the first stress groove 9 is shaped as a square, or, as shown in FIG. 11 that is another schematic diagram of the binding region 4 provided by some embodiments of the present disclosure, the first stress groove 9 is a rounded square. That is, an angle between two adjacent sides of the first stress groove 9 is 90°, or two adjacent straight sides of the first stress groove 9 are connected by an arc edge. Such design can avoid that the angle between two adjacent sides of the first stress groove 9 is smaller than 90°, thereby avoiding the formation of a starting point or a focus point of the layer peeling for peeling of the layer and then avoiding a large area of layer peeling.

FIG. 12 is another schematic diagram of a first blank region 8 provided by some embodiments of the present disclosure. In some embodiments, as shown in FIG. 12, in at least one first blank region 8, at least one first stress groove 9 includes at least two sub-grooves 14 spaced apart from each other in the extending direction of the first stress groove 9.

This kind of first stress groove 9 is discontinuous, but includes at least two sub-grooves 14 that are spaced apart from each other. In this way, an inorganic layers are retained between adjacent sub-grooves 14, which is conducive to strengthening adhesion between the layers of a same type in a local region, suppressing the risk of the layer peeling of the inorganic layer 7, and improving the layer reliability.

In some embodiments, referring to FIG. 12 again, a distance L1 between two adjacent sub-grooves 14 in the first stress groove 9 satisfies p2≤L1≤3×p2, where p2 is a sum of a groove width of the first stress groove 9 and a groove spacing between this first stress groove 9 and its adjacent first stress groove 9, and p2 can also be understood as a pitch of the first stress groove 9.

A minimum value of L1 can be set to p2, which can ensure a sufficient space between two adjacent sub-grooves 14, sufficient contact area between the inorganic layer 7 between two adjacent sub-grooves 14, and a relatively high adhesive force of the layer. Then, setting the maximum value of L1 to 3×p2 can also avoid a relatively short extension length of the sub-troughs 14 caused by an excessively large spacing between the sub-grooves 14, thereby allowing the sub-grooves 14 to have a sufficiently long stress-releasing path to improve the stress relief effect.

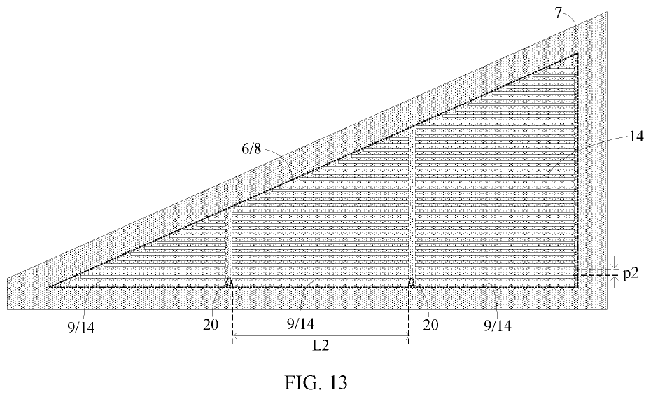

FIG. 13 is another schematic diagram of a first blank region 8 provided by the embodiment of the present disclosure. In some embodiments, as shown in FIG. 13, a first interval 20 is formed between two adjacent sub-grooves 14 in the first stress groove 9. A distance L2 between two adjacent first intervals 20 satisfies L2≥15×p2, where p2 is a sum of the groove width of the first stress groove and the groove spacing between this first stress groove and its adjacent first stress groove. In this way, the sub-groove 14 between two adjacent first intervals 20 can have a sufficient extension length, that is, there can be a sufficient stress-releasing path between two adjacent first intervals 20, reducing the risk of layer peeling.

However, considering that for some first blank regions 8 with smaller areas, a size of the first blank region 8 in the extending direction of the first stress groove 9 may be smaller, and it is difficult to realize a goal of that a distance between two adjacent first intervals 20 is designed to be greater than or equal to 15×p2. In view of the above, the distance between two adjacent first intervals 20 can be designed to be positively related to the size of the first blank region 8 in the extending direction of the first stress groove 9, That is, if the size of the first blank region 8 in the extending direction of the first stress groove 9 is relatively large, the distance between two adjacent first intervals 20 can be designed to be relatively large. If the size of the stress groove 9 in the extending direction is relatively small, the distance between two adjacent first intervals 20 can be designed to be relatively small.

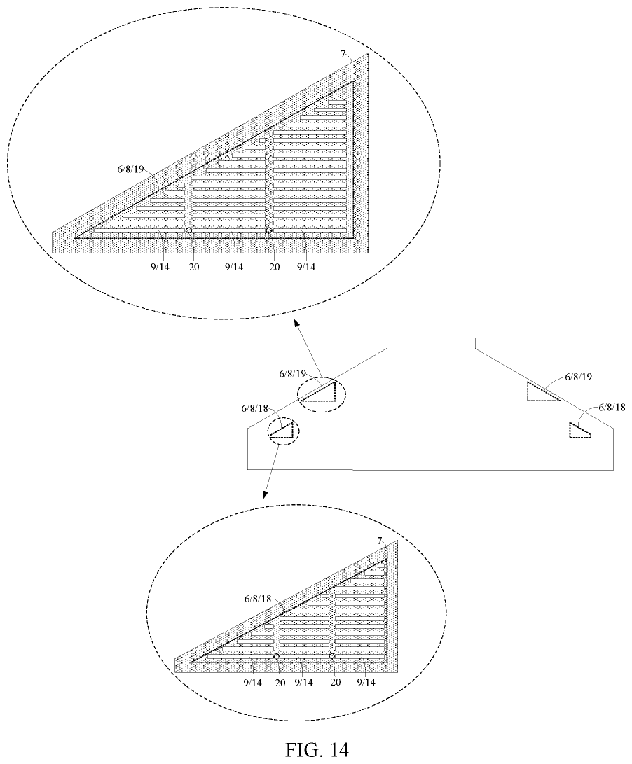

Based on the above, as shown in FIG. 14 that is another schematic diagram of a first blank region 8 provided by some embodiments of the present disclosure, the first blank region 8 includes a first blank sub-region 18 and a second blank sub-region 19, and a size of the first blank sub-region 18 in the extending direction of the first stress groove 9 inside the first blank sub-region is smaller than a size of the second blank sub-region 19 in the extending direction of the first stress groove 9 inside the second blank sub-region 19. A distance between two adjacent first intervals 20 in the first stress groove 9 in the first blank sub-region 18 is smaller than a distance between two adjacent first intervals 20 in the first stress groove 9 in the second blank sub-region 19.

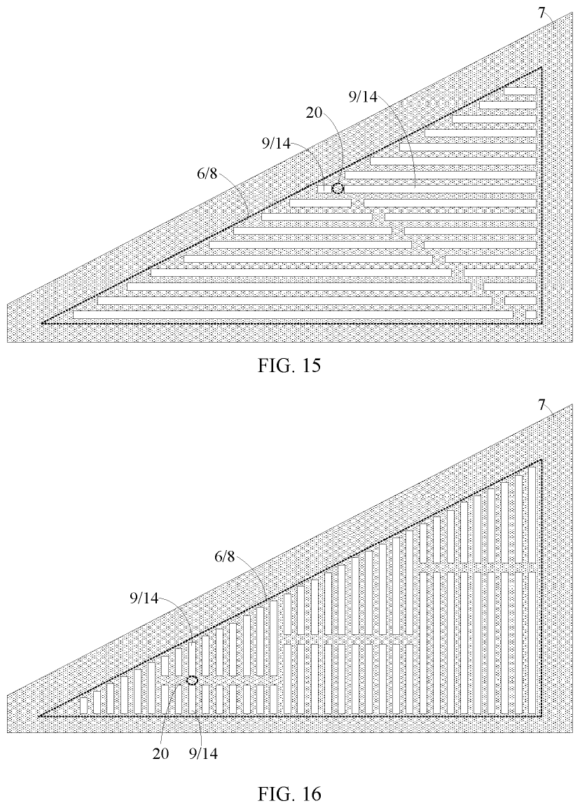

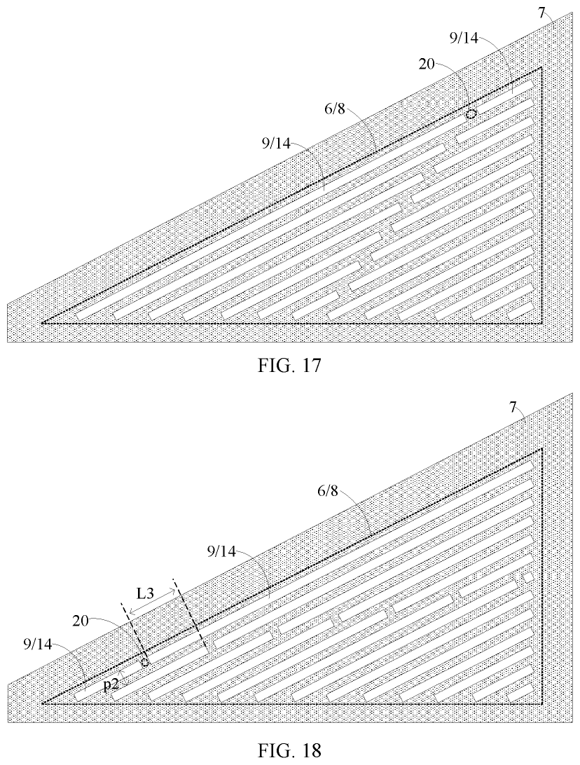

FIG. 15 is another schematic diagram of a first blank region 8 provided by some embodiments of the present disclosure. FIG. 16 is another schematic diagram of a first blank region 8 provided by some embodiments of the present disclosure. FIG. 17 is another schematic diagram of a first blank region 8 provided by some embodiments of the present disclosure. In some embodiments, as shown in FIGS. 15 to 17, a first interval is formed between two adjacent sub-grooves 14 in the first stress groove 9, and the first intervals 20 in at least one first stress groove 9 in at least one first blank region 8 are staggered from each other in a direction perpendicular to the extending direction of the first stress groove 9. Such arrangement where the first spaces 20 are arranged in a ladder-like arrangement can enhance the pulling force between the layers, which is beneficial to reducing the risk of mutual peeling between different inorganic layers 7 and reducing the risk of the continuous extension of the layer peeling in the direction perpendicular to the extending direction of the first stress groove 9.

FIG. 18 is another schematic diagram of a first blank region 8 provided by some embodiments of the present disclosure. In some embodiments, as shown in FIG. 18, for the two first intervals 20 that are closest to each other and staggered from each other, a distance L3 between the two first intervals 20 in the direction parallel to the extending direction of the first stress groove 9 is greater than or equal to 3×p2, where p2 is a sum of a groove width of the first stress groove 9 and a groove spacing between this first stress groove 9 and its adjacent first stress groove 9, to enhance the pulling force between layers, reduce the risk of layer peeling, and reduce the risk of continuously extending of the layer peeling.

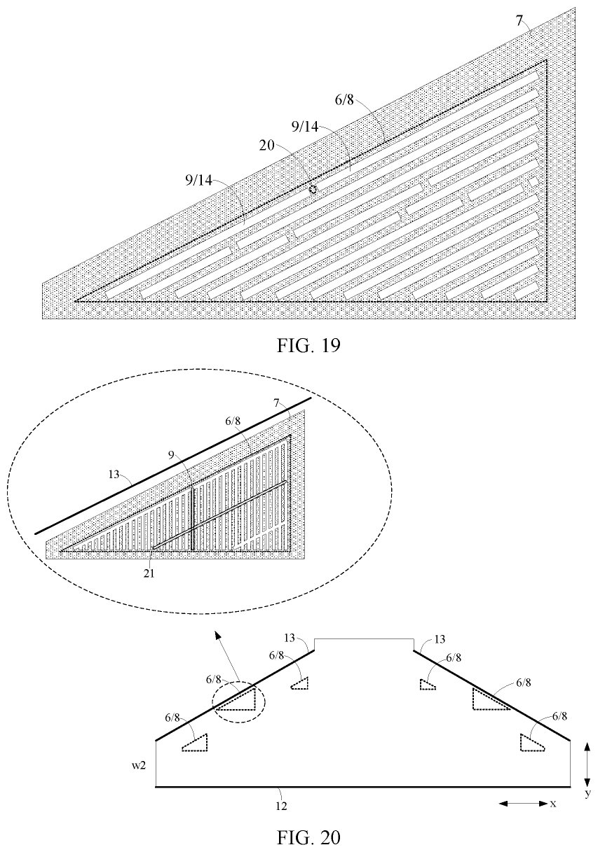

FIG. 19 is another schematic diagram of a first blank region 8 provided by some embodiments of the present disclosure. In some embodiments of the present disclosure, as shown in FIG. 19, the intervals between adjacent sub-grooves 14 in adjacent first stress groove 9 can also be staggered from each other or randomly distributed. Such configuration can also enhance the pulling force between the layers to a greater extent, reduce the risk of layer peeling, and reduce the risk of continuously extending of the layer peeling.

FIG. 20 is another schematic diagram of a first blank region 8 provided by some embodiments of the present disclosure. In some embodiments, as shown in FIG. 20, the inorganic layer 7 in at least one first blank region 8 includes a second stress groove 21, an extending direction of the second stress groove 21 intersects the extending direction of the first stress groove 9, and the second stress groove 21 and the first stress groove 9 communicate to lengthen the stress-releasing path and reduce the risk of layer peeling.

In some embodiments, referring to FIG. 20 again, the binding region 4 includes a first outer edge 12. The first outer edge 12 is an edge of the binding region 4 that is farthest away from the bending region 3. The first outer edge 12 extends along the first direction x. The binding region 4 can include a second outer edge 13, an angle between an extending direction of the second outer edge 13 and the first direction x is smaller than 90° and not equal to 0°.

At least one first blank region 8 is adjacent to the second outer edge 13. For the first blank region 8 adjacent to the second outer edge 13, the inorganic layer 7 in the first blank region 8 can include a second stress groove 21, the extending direction of the first stress groove 9 is parallel to the extending direction of the second outer edge 13, and the extending direction of the second stress groove 21 intersects with the extending direction of the second outer edge 13.

In combination with the foregoing analysis, in a COP type flexible display panel, the main stress point when the indenter presses down will be closer to the outer edge of the flexible display panel, and with the first stress groove 9 and the second stress groove 21 having the above extending directions provided in the first blank region 8 adjacent to the second outer edge 13, not only the stress can be released to a greater extent, but also cutting cracks and the layer peeling at the cutting line can be blocked to a greater extent.

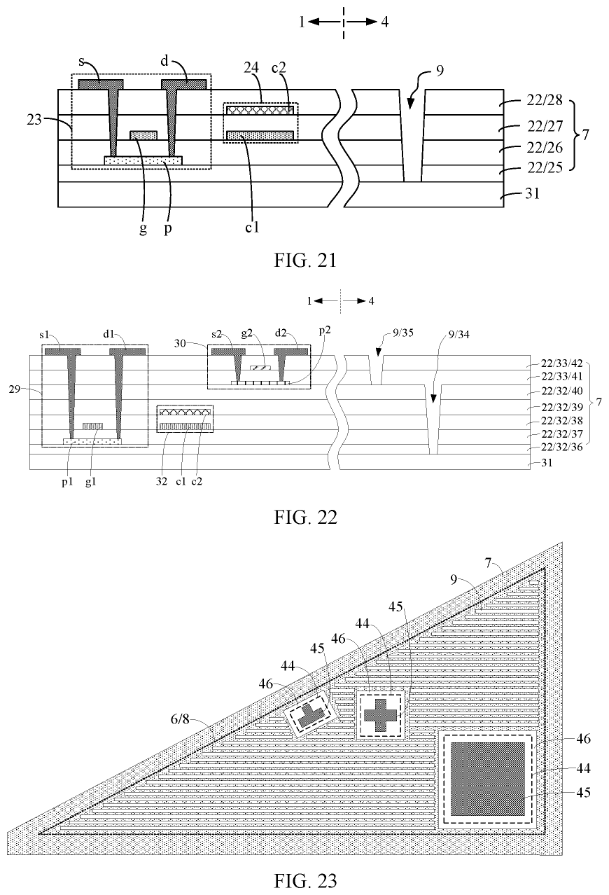

In some embodiments, as shown in FIG. 21, which is a cross-sectional view of a flexible display panel provided by some embodiments of the present disclosure, the inorganic layer 7 includes multiple inorganic sub-layers 22, and the first stress groove 9 passes through these inorganic sub-layers 22. Based on such structure, the first stress groove 9 can be formed by only one mask process when the last inorganic sub-layer 22 is formed, and the manufacturing process of the first stress groove 9 is simpler.

Such structure may be more suitable for low temperature poly-silicon (LTPS) type flexible display panels. In this type of flexible display panel, with reference to FIG. 21, a transistor 23 and a first capacitor 24 are provided in the display region 1, and the multiple inorganic sub-layers 22 may include a first buffer layer 25, a first gate insulating layer 26, a first capacitor insulating layer 27, and a first interlayer insulating layer 28. The first buffer layer 25 is located between the substrate 31 and an active layer p of the transistor 23, the first gate insulating layer 26 is located between the active layer p and a gate g of the transistor 23 and between the active layer p and a first plate c1 of the first capacitor 24, and the first capacitor insulating layer 27 is located between the first plate c1 of the first capacitor 24 and the gate g of the transistor 23 and between the first plate c1 and a second plate c2 of the first capacitor 24, and the first interlayer insulating layer 28 is located between the second plate c2 of the first capacitor 24 and a first electrode s of the transistor 23 and is located between the second plate c2 of the first capacitor 24 and a second electrode d of the transistor 23. The first stress groove 9 passes through the first buffer layer 25, the first gate insulating layer 26, the first capacitor insulating layer 27, and the first interlayer insulating layer 28.

The number of inorganic sub-layers 22 in this type of flexible display panel is relatively small. When forming the first stress groove 9 that passes through multiple inorganic sub-layers 22, the process requirements are relatively lower, and the reliability of the first stress groove 9 is relatively high.

In some embodiments, as shown in FIG. 22, which is another cross-sectional view of a flexible display panel provided by some embodiments of the present disclosure, the inorganic layer 7 includes multiple inorganic sub-layers 22. The inorganic sub-layers 22 includes at least one first inorganic sub-layer 32 and at least one second inorganic sub-layer 33. The second inorganic sub-layer 33 is located at a side of the first inorganic sub-layer 32 facing towards a light-exiting direction of the flexible display panel. The first stress grooves 9 include a first stress sub-groove 34 and a second stress sub-groove 35. The first stress sub-groove 34 passes through the first inorganic sub-layer 32, and the second stress sub-groove 35 passes through the second inorganic sub-layer 33. In a direction perpendicular to the plane of the flexible display panel, the first stress sub-groove 34 and the second stress sub-groove 35 do not overlap.

In this structure, when forming the last first inorganic sub-layer 32, one mask process can be used to form the first stress sub-groove 34 that passes through all first inorganic sub-layers 32. When forming the last second inorganic sub-layer 33, one mask process can be used to form the second stress sub-groove 35 penetrating all second inorganic sub-layer 33. By staggering the first stress sub-groove 34 and the second stress sub-groove 35 in the direction perpendicular to the substrate 31, the layer peeling in the direction perpendicular to the substrate 31 can be prevented from extending, thereby improving the peeling effect.

This structure is more suitable for low temperature polycrystalline oxide (LTPO) flexible display panel. This type of flexible display panel is provided with two types of transistors, i.e., a metal oxide transistor 29 and a low temperature poly-silicon transistor 30, so the number of inorganic sub-layers 22 will be relatively large. For example, referring to FIG. 22, the display panel includes the metal oxide transistor 29, the low-temperature poly-silicon transistor 30, and a second capacitor 32. Multiple inorganic sub-layers 22 may include a second buffer layer 36, a second gate insulating layer 37, a second capacitor insulating layer 38, a second interlayer insulating layer 39, a first oxide gate insulating layer 40, a second oxide gate insulating layer 41, and a third interlayer insulating layer 42. The second buffer layer 36 is located between the substrate 31 and an active layer p1 of the metal oxide transistor 29. The second gate insulating layer 37 is located between the active layer p1 of the metal oxide transistor 29 and a gate g1 and between the active layer p1 of the metal oxide transistor 29 and the first plate c1 of the second capacitor 32. The second capacitor insulating layer 38 is located between the gate g1 of the metal oxide transistor 29 and a second electrode plate of the second capacitor 32 and between the first electrode plate c1 and the second electrode plate c2 of the second capacitor 32. The second interlayer insulating layer 39 and the first oxide gate insulating layer 40 are located between the second electrode plate c2 of the second capacitor 32 and an active layer p2 of the low-temperature poly-silicon transistor 30. The second oxide gate insulating layer 41 is located between the active layer p2 of the low-temperature poly-silicon transistor 30 and a gate g2 of the low-temperature poly-silicon transistor 30. The third interlayer insulating layer is located between the gate g2 of the low-temperature poly-silicon transistor 30 and a first electrode s2 and a second electrode s2 of the low-temperature poly-silicon transistor 30. Also, the third interlayer insulating layer is located between the gate g2 of the low-temperature poly-silicon transistor 30 and a first electrode s1 and a second electrode s1 of the metal oxide transistor 29.

Any adjacent inorganic sub-layers 22 among multiple inorganic sub-layers 22 can be set as the first inorganic sub-layer 32, and the remaining inorganic sub-layers 22 can be set as the second inorganic sub-layer 33. For example, the second buffer layer 36, the second gate insulating layer 37, the second capacitor insulating layer 38, the second interlayer insulating layer 39, and the first oxide gate insulating layer 40 are the first inorganic sub-layers 32, and the second oxide gate insulating layer 42 and the third interlayer insulating layer 43 are the second inorganic sub-layers 33.

In some embodiments, as shown in FIG. 23 that is another schematic diagram of a first blank region 8 provided by some embodiments of the present disclosure, at least one first blank region 8 includes a clearance region 44, and an alignment mark 45 is provided in the clearance region 44. The inorganic layer 7 in at least one first blank region 8 includes a third stress groove 46, and the clearance region 44 is located in the third stress groove 46 in the direction perpendicular to the plane of the flexible display panel.

When at least one first blank region 8 includes the clearance region 44, a third stress groove 46 corresponding to the clearance region 44 can also be provided to release the stress near the clearance region 44 and reduce the layer peeling caused by the stress concentration in the clearance region 44. When providing the third stress groove 46 in the embodiments of the present disclosure, the entire clearance region 44 is arranged in the third stress groove 46, that is, all the inorganic layer 7 in the entire clearance region 44 is dug out, so as to avoids a complexity layer pattern caused by digging out part of the inorganic layer 7 and leaving part of the inorganic layer 7 in the clearance region 44, thereby avoiding affecting capturing the alignment mark 45.

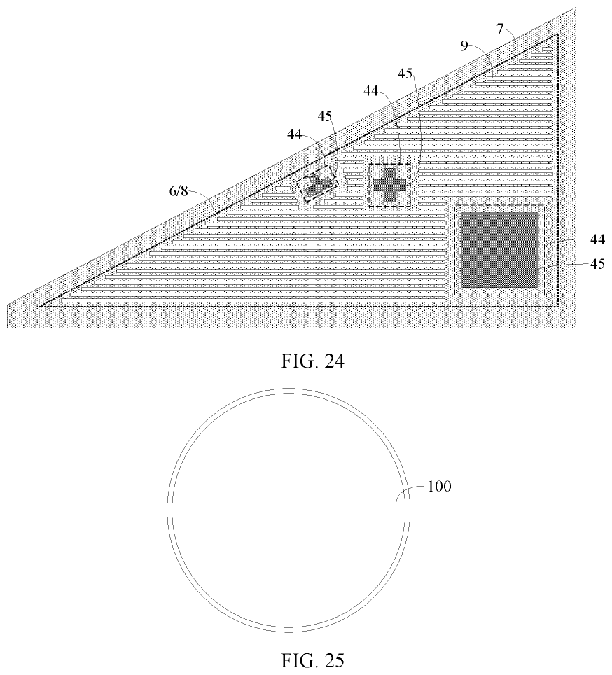

In some embodiments, as shown in FIG. 24 that is another schematic diagram of a first blank region 8 provided by some embodiments of the present disclosure, when ensuring the accuracy of capturing the alignment mark 45 in advance, no stress groove can be provided in the clearance region 44. A is provided, that is, the inorganic layer 7 covers the clearance region 44, so that the original layer design in the clearance region 44 is not changed, and it is avoided that the grabbing of the alignment mark 45 is affected to a greater extent.

In some embodiments, the first blank region 8 may include one, two or more clearance regions 44, and a shape of the alignment mark 45 in the clearance region 44 may be a cross, a semi-cross or a square, which is not specifically limited in the embodiments of the present disclosure.

In some embodiments, referring to FIG. 5 again, the inorganic layer 7 includes an anti-crack groove 11 adjacent to the outer edge of the flexible display panel, and the anti-crack groove 11 extends along at least the outer edge of the binding region 4. A groove width d11 of the anti-crack groove 11 and a groove width a2 of the first stress groove 9 satisfy 0.5×a1≤a2≤5×a1. In some embodiments, a groove spacing b1 between adjacent anti-crack grooves 11 and a groove spacing b2 between adjacent first stress grooves 9 satisfy 0.25×b1≤b2≤5×b1.

For example, in one structure, the groove width of the anti-crack groove 11 is 7 μm, and the groove spacing between the anti-crack grooves 11 is 4 μm. In some embodiments of the present disclosure, the groove width of the first stress groove 9 is set to 7 μm, and the groove spacing between the first stress grooves 9 is set to 4 μm.

By setting the minimum value of the groove width of the first stress groove 9 to 0.5×a1, it can be avoided that the first stress groove 9 is too thin to affect the release of stress. By setting a maximum value of the groove width of the first stress groove 9 to 5×a1, it is avoided that the first stress groove 9 is too wide, which ensures that a sufficient number of the first stress grooves 9 can be provided in the first blank region 9 to ensure the stress relief effect.

By setting the minimum value of the groove spacing between adjacent first stress grooves 9 to 0.25×b1, it is avoided that the inorganic layer dam remaining between adjacent first stress grooves 9 is too narrow, thereby ensuring sufficient adhesion between the inorganic layers 7 at the groove spacing. By setting the maximum value of the groove spacing between adjacent first stress grooves 9 to 5×b1, it is avoided that a long distance is formed between the first stress grooves 9, which ensure stress releasing effect.

In some embodiments of the present disclosure, the groove width and the groove spacing of the first stress groove 9 are set based on process limit values. For example, the minimum groove width and the minimum groove spacing that can be achieved with the process conditions are 3 μm. In some embodiments of the present disclosure, the groove width of the first stress groove 9 and the groove spacing between the first stress grooves 9 can be designed to be 3 μm.

Some embodiments of the present disclosure provide a flexible display device, as shown in FIG. 25 that is a schematic diagram of a flexible display device provided by some embodiments of the present disclosure, the flexible display device includes the above flexible display panel 100. The specific structure of the flexible display panel 100 has been described in detail in the above embodiments and will not be repeated herein. The flexible display device shown in FIG. 25 is only a schematic illustration. The flexible display device can be any electronic device with a display function, such as a mobile phone, a tablet computer, a notebook computer, an electronic paper book, or a television.

The above are only exemplary embodiments of the present disclosure and are not intended to limit the present disclosure. Any modifications, equivalent substitutions, improvements, etc. made within the principles of the present disclosure shall fall within the scope of the present disclosure.

Finally, the above embodiments are only used to illustrate the technical solution of the present disclosure, but not to limit it. Although the present disclosure has been described in detail with reference to the foregoing embodiments, those skilled in the art should understand that modifications still can be made to the technical solutions described in the foregoing embodiments, or some or all of the technical features can be equivalently substituted. However, these modifications or substitutions do not cause the essence of the corresponding technical solutions to depart from the scope of the technical solutions of the embodiments of the present disclosure.

What is claimed is:

1. A flexible display panel, having a display region and a non-display region, the flexible display panel comprising an inorganic layer and a signal lead-out line,
wherein the non-display region comprises a bending region and a binding region, the bending region being located between the display region and the binding region, the binding region comprising a wiring region and a blank region, and the signal lead-out line being located in the wiring region;
wherein the inorganic layer is located in the display region and the non-display region; and
wherein the blank region comprises at least one first blank region, and wherein a portion of the inorganic layer that is located in one of the at least one first blank region comprises at least one first stress groove.

2. The flexible display panel according to claim 1, wherein the inorganic layer further comprises at least one anti-crack groove adjacent to an outer edge of the flexible display panel, the at least one anti-crack groove extends along the outer edge within at least the binding region; and
the blank region is located at a side of the at least one anti-crack groove away from the outer edge.

3. The flexible display panel according to claim 2, wherein the at least one anti-crack groove comprises at least two anti-crack grooves, and one of the at least one first blank region is adjacent to one of the at least two anti-crack grooves; and
wherein, in the first blank region adjacent to the anti-crack groove, a distance between one of the at least one first stress groove and one of the at least two anti-crack grooves is greater than or equal to p1, where p1 is a sum of a groove width of the anti-crack groove and a groove spacing between one of the anti-crack groove and another adjacent one of the at least two anti-crack grooves.

4. The flexible display panel according to claim 1, wherein the at least one first stress groove comprises at least two first stress grooves, wherein the at least two first stress grooves located in one of the at least one first blank region extend in a same direction.

5. The flexible display panel according to claim 1, wherein the binding region comprises a first outer edge, wherein the first outer edge is an edge of the binding region that is farthest from the bending region, and the first outer edge extends along a first direction; and
wherein, in one of the at least one first blank region, the at least one first stress groove extends in a direction perpendicular to the first direction.

6. The flexible display panel according to claim 1, wherein the binding region comprises a first outer edge, wherein the first outer edge is an edge of the binding region that is farthest from the bending region, and the first outer edge extends along a first direction; and
wherein, in one of the at least one first blank region, one of the at least one first stress groove extends in a direction parallel to the first direction.

7. The flexible display panel according to claim 1, wherein the binding region comprises a first outer edge and a second outer edge, wherein the first outer edge is an edge of the binding region that is farthest from the bending region, the first outer edge extends along a first direction, and an angle between an extending direction of the second outer edge and the first direction is smaller than 90° and not equal to 0°; and
wherein one of the at least one first blank region is adjacent to the second outer edge, one of the at least one first stress groove in the first blank region extends in a direction parallel to the extending direction of the second outer edge, or the one of the at least one first stress groove in the first blank region extends in a direction perpendicular to the extending direction of the second outer edge.

8. The flexible display panel according to claim 1, wherein one of the at least one first stress groove is a square or a rounded square.

9. The flexible display panel according to claim 1, wherein, in one of the at least one first blank region, one of the at least one first stress groove comprises at least two sub-grooves spaced apart from one another in an extending direction of the first stress groove.

10. The flexible display panel according to claim 9, wherein the at least one first stress groove comprises the at least two first stress grooves, and a distance L1 between two adjacent sub-grooves of the at least two sub-grooves in one of the at least two first stress grooves satisfies: p2≤L1≤3×p2, where p2 denotes a sum of a groove width of the one of the at least two first stress grooves and a spacing between one of the at least two first stress grooves and another adjacent one of the at least two first stress grooves.

11. The flexible display panel according to claim 9, wherein a first interval is formed between two adjacent sub-grooves of the at least two sub-grooves in one of the at least one first stress groove; and a distance L2 between two adjacent first intervals satisfies: L2≥15×p2, where p2 denotes a sum of a groove width of the one of the at least two first stress grooves and a spacing between one of the at least two first stress grooves and another adjacent one of the at least two first stress grooves.

12. The flexible display panel according to claim 9, wherein a first interval is formed between two adjacent sub-grooves of the at least two sub-grooves in one of the at least one first stress groove; and
wherein, in one of the at least one first blank region, first intervals in one of the at least one first stress groove are staggered from each other in a direction perpendicular to an extending direction of the at least one first stress groove.

13. The flexible display panel according to claim 12, wherein, for two first intervals that are closest to each other and staggered from each other, a distance between the two first intervals in a direction parallel to the extending direction of the first stress groove is greater than or equal to 3×p2, where p2 denotes a sum of a groove width of the one of the at least two first stress grooves and a spacing between the one of the at least two first stress grooves and another adjacent one of the at least two first stress grooves.

14. The flexible display panel according to claim 1, wherein the inorganic layer in one of the at least one first blank region further comprises a second stress groove, an extending direction of the second stress groove intersects an extending direction of the at least one first stress groove, and the second stress groove communicates with one of the at least one first stress groove.

15. The flexible display panel according to claim 14, wherein the binding region comprises a first outer edge and a second outer edge, wherein the first outer edge is an edge of the binding region that is farthest from the bending region, the first outer edge extends along a first direction, and an angle between an extending direction of the second outer edge and the first direction is smaller than 90° and not equal to 0°; and
wherein one of the at least one first blank region is adjacent to the second outer edge, the inorganic layer in the first blank region further comprises the second stress groove, the extending direction of the first stress groove is parallel to the extending direction of the second outer edge, and the extending direction of the second stress groove intersects with the extending direction of the second outer edge.

16. The flexible display panel according to claim 1, wherein the inorganic layer comprises a plurality of inorganic sub-layers, and the at least one first stress groove penetrates through the plurality of inorganic sub-layers.

17. The flexible display panel according to claim 1, wherein the inorganic layer comprises a plurality of inorganic sub-layers, wherein the plurality of inorganic sub-layers comprises at least one first inorganic sub-layer and at least one second inorganic sub-layer, wherein the second inorganic sub-layer is located at a side of the first inorganic sub-layer facing towards a light-exit direction of the flexible display panel; and
wherein one of the at least one first stress groove comprises a first stress sub-groove and a second stress sub-groove, wherein the first stress sub-groove penetrates through the first inorganic sub-layer, the second stress sub-groove penetrates through the second inorganic sub-layer, and the first stress sub-groove and the second stress sub-groove do not overlap in a direction perpendicular to a plane of the flexible display panel.

18. The flexible display panel according to claim 1, wherein one of the at least one first blank region further comprises a clearance region, and an alignment mark is provided in the clearance region; and
wherein the inorganic layer in one of the at least one first blank region further comprises a third stress groove, wherein the clearance region is located in the third stress groove in a direction perpendicular to a plane of the flexible display panel.

19. The flexible display panel according to claim 1, wherein the inorganic layer further comprises at least one anti-crack groove adjacent to an outer edge of the flexible display panel, the at least one anti-crack groove extends along the outer edge within at least the binding region; and
wherein a groove width a1 of one of the at least one anti-crack groove and a groove width a2 of one of the at least one first stress groove satisfy 0.5×a1≤a2≤5×a1; or wherein the at least one first stress groove comprises at least two first stress grooves, the at least one anti-crack groove comprises at least two anti-crack grooves, and a groove spacing between adjacent anti-crack grooves off the at least two anti-crack grooves and a groove spacing between adjacent first stress grooves of the at least two first stress grooves satisfy 0.25×b1≤b2≤5×b1.

20. A flexible display device, comprising a flexible display panel, wherein the flexible display panel has a display region and a non-display region, and wherein the flexible display device comprises an inorganic layer and a signal lead-out line,
wherein the non-display region comprises a bending region and a binding region, the bending region being located between the display region and the binding region, the binding region comprising a wiring region and a blank region, and the signal lead-out line being located in the wiring region;
wherein the inorganic layer is located in the display region and the non-display region; and
wherein the blank region comprises at least one first blank region, and wherein a portion of the inorganic layer that is located in one of the at least one first blank region comprises at least one first stress groove.
